(19) United States
(12) Patent Application Publication
(10) Pub. No.: US 2025/0300019 A1
(43) Pub. Date: Sep. 25, 2025

(54) METHOD FOR MANUFACTURING ELECTRONIC DEVICE AND ELECTRONIC DEVICE

(71) Applicants: Kabushiki Kaisha Toshiba, Tokyo (JP); Toshiba Electronic Devices & Storage Corporation, Tokyo (JP)

(72) Inventor: Tomohiro SAITO, Yokohama Kanagawa (JP)

(21) Appl. No.: 19/046,482

(22) Filed: Feb. 5, 2025

(30) Foreign Application Priority Data
Mar. 19, 2024 (JP) 2024-044110

(51) Int. Cl. H01L 21/768; H01L 23/48

(52) U.S. Cl. CPC H01L 21/76898; H01L 23/481

(57) ABSTRACT

A method for manufacturing an electronic device includes forming a recess on a first surface side of a substrate. The substrate has the first surface and a second surface opposite to the first surface. The method includes forming a protective film inside the recess. An end portion of the protective film covers a bottom surface of the recess. A height of the protective film from the bottom surface is lower than a height of the first surface. The method includes processing the substrate from the second surface side to expose the end portion of the protective film to form a through hole in the substrate from at least a part of the recess. An opening of the through hole on a side opposite to the first surface is closed by the protective film. The method includes removing the protective film provided in the through hole.

### CROSS-REFERENCE TO RELATED APPLICATIONS

This application is based upon and claims the benefit of priority from Japanese Patent Application No. 2024-044110, filed on Mar. 19, 2024; the entire contents of which are incorporated herein by reference.

### FIELD

Embodiments described herein relate to a method for manufacturing an electronic device and to an electronic device.

### BACKGROUND

There is an electronic device including a substrate having a through hole. For example, an electron beam passes through the through hole. It is desirable to reduce the occurrence of defects in the electronic device.

### BRIEF DESCRIPTION OF THE DRAWINGS

FIG. 1 is a schematic cross-sectional view of an electronic device according to an embodiment;

FIG. 2 is a schematic plan view of the electronic device according to the embodiment;

FIGS. 3A to 3F are schematic cross-sectional views illustrating a method for manufacturing the electronic device according to the embodiment;

FIGS. 4A to 4E are schematic cross-sectional views illustrating the method for manufacturing the electronic device according to the embodiment;

FIG. 5 is a schematic cross-sectional view of the electronic device according to the embodiment;

FIG. 6 is a schematic cross-sectional view of an electronic device according to the embodiment;

FIG. 7 is a schematic cross-sectional view of an electronic device according to the embodiment;

FIG. 8 is a schematic cross-sectional view of an electronic device according to the embodiment; and

FIG. 9 is a schematic cross-sectional view of an electronic device according to the embodiment.

### DETAILED DESCRIPTION

According to an embodiment, a method for manufacturing an electronic device includes forming a recess on a first surface side of a substrate. The substrate has the first surface and a second surface opposite to the first surface. The method includes forming a protective film inside the recess. An end portion of the protective film covers a bottom surface of the recess. A height of the protective film from the bottom surface is lower than a height of the first surface. The method includes processing the substrate from the second surface side to expose the end portion of the protective film to form a through hole in the substrate from at least a part of the recess. An opening of the through hole on a side opposite to the first surface is closed by the protective film. The method includes removing the protective film provided in the through hole.

Hereinafter, embodiments of the invention will be described with reference to the drawings.

The drawings are schematic or conceptual, and the relationship between the thickness and width of each portion, the proportions of sizes among portions, and so on are not necessarily the same as the actual values. Even the dimensions and proportion of the same portion may be illustrated differently depending on the drawing.

In the specification and drawings, components similar to those described in regard to a drawing thereinabove are marked with like reference numerals, and a detailed description is omitted as appropriate.

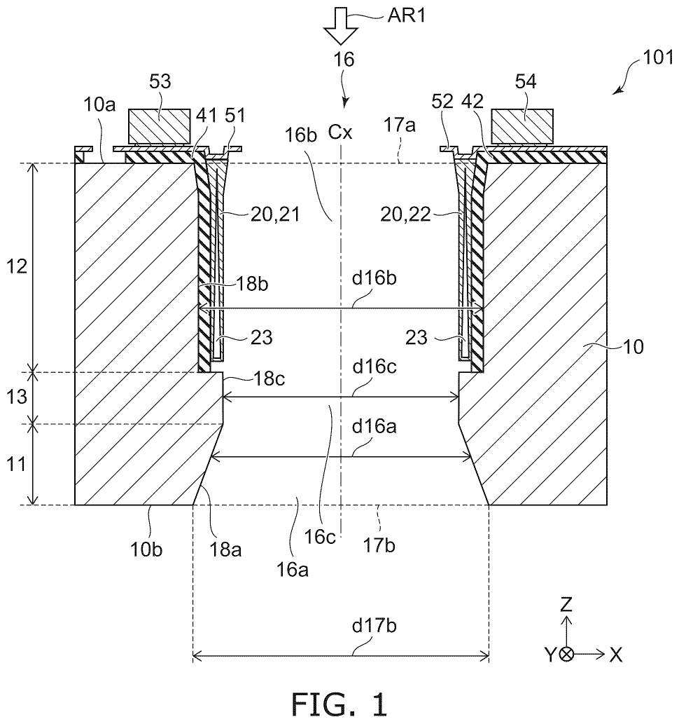

FIG. 1 is a schematic cross-sectional view of an electronic device according to an embodiment.

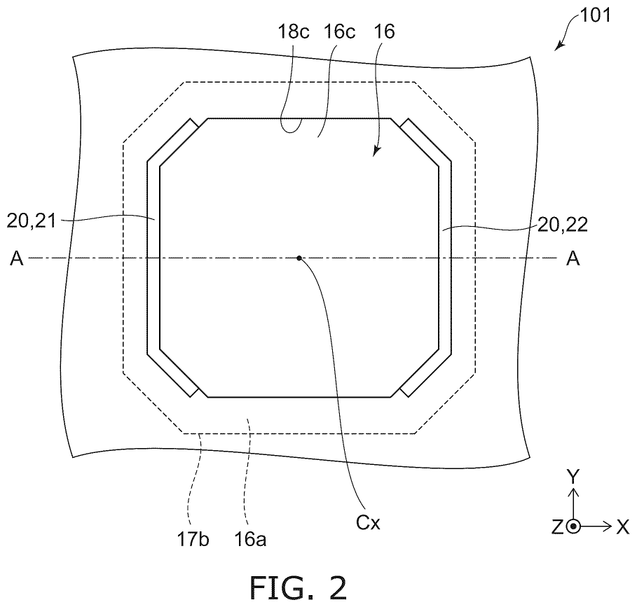

FIG. 2 is a schematic plan view of the electronic device according to the embodiment.

FIG. 1 shows a cross section of an electronic device 101 according to the embodiment. As shown in FIG. 1, the electronic device 101 includes a substrate 10 and an electrode 20. For example, a first electrode 21 and a second electrode 22 are provided as a pair of electrodes 20.

FIG. 2 is a plan view of the substrate 10 and the electrode 20 as viewed along the arrow AR1 shown in FIG. 1. In FIG. 2, components other than the substrate 10 and the electrode 20 are omitted as appropriate for the sake of convenience. FIG. 1 corresponds to a cross section taken along line A-A in FIG. 2.

As shown in FIG. 1, the substrate 10 has a first surface 10a and a second surface 10b opposite to the first surface. The first surface 10a is, for example, a main surface of the substrate 10.

In the description of the embodiment, a direction from the second surface 10b toward the first surface 10a is defined as a Z-direction (first direction). The Z-direction is, for example, a thickness direction of the substrate 10. A direction perpendicular to the Z-direction is defined as an X-direction (second direction), and a direction perpendicular to the Z-direction and the X-direction is defined as a Y-direction. The first surface 10a and the second surface 10b are, for example, surfaces extending along an X-Y plane perpendicular to the Z-direction.

The substrate 10 has a through hole 16. The through hole 16 extends in the Z-direction from the first surface 10a to the second surface 10b and penetrates the substrate 10. The through hole 16 connects an opening 17a located in the first surface 10a and an opening 17b located in the second surface 10b.

The electrode 20 is provided in the through hole 16 and extends in the Z-direction. The electrode 20 is provided along the inner surface of the through hole 16, extends in the Z-direction, and includes, for example, a plate-shaped portion extending in the Y-direction. The pair of electrodes 20 (the first electrode 21 and the second electrode 22) are disposed so as to face each other across a center Cx of the through hole 16. The center Cx is the center of the through hole 16 in the X-Y plane, in other words, a central axis extending in the Z-direction.

The electrode 20 is, for example, hollow. That is, the electrode 20 has, for example, a cavity 23 inside the electrode 20.

The electronic device 101 is used, for example, to control an electron beam passing through the through hole 16. For example, the electronic device 101 controls the magnitude of a voltage applied between the pair of electrodes 20, thereby controlling a travel direction of an electron beam passing between the pair of electrodes 20 and passing through the through hole 16. The electronic device 101 is applied to an apparatus that controls an electron beam to irradiate an object and that performs observation, processing, and so on, such as an electron microscope that performs surface observation with an electron beam, an electron beam drawing apparatus that draws a fine pattern on a mask or a wafer, or an inspection apparatus that scans a surface with an electron beam to detect a defect. The electronic device 101 is, for example, an electron beam control device, such as an electrostatic lens or a deflector.

However, the application of the electronic device according to the embodiment is not limited to the above. The embodiment is applicable to any device having a through hole provided in a substrate. For example, the embodiment is applicable to any device in which an electrode is provided as appropriate in the through hole when necessary. The number of electrodes provided in the through hole 16 is not limited to two, and may be one or three or more.

The substrate 10 includes a first portion 11 and a second portion 12. In this example, the substrate 10 further includes a third portion 13.

The first portion 11 includes a part (hole portion 16a) of the through hole 16. The first portion 11 is a portion that includes the second surface 10b of the substrate 10. The first portion 11 forms the opening 17b of the through hole 16 proximate to the second surface 10b. The first portion 11 defines the diameter of a part (hole portion 16a) of the through hole 16 between the first surface 10a and the second surface 10b. The diameter is, for example, a length along the X-direction. The magnitude of the diameter of the through hole corresponds to, for example, the magnitude of the cross-sectional area of the through hole.

In this example, a diameter d16a of the through hole (the diameter of the hole portion 16a) in the first portion 11 increases as the hole portion 16a extends toward the opening 17b in the Z-direction. For example, an inner surface 18a of the through hole 16 (the inner surface of the hole portion 16a) in the first portion 11 is an inclined surface that is inclined with respect to the Z-direction. For example, the entire inner surface 18a is inclined so as to be away from the center Cx as the inner surface 18a extends toward the opening 17b in the Z-direction. For example, in the first portion 11, the through hole 16 becomes larger in the X-Y plane in an isotropic manner as the through hole 16 extends toward the opening 17b in the Z-direction.

As described above, in this example, the inner surface 18a is an inclined surface, and the diameter d16a continuously increases as the through hole 16 extends toward the opening 17b in the Z-direction. The inner surface 18a is not limited to this, and in the embodiment, for example, one or more steps may be provided on the inner surface 18a, and the diameter d16a may increase stepwise as the through hole 16 extends toward the opening 17b in the Z-direction.

30 The second portion 12 is located between the first portion and the first surface 10a, and includes another part (hole portion 16b) of the through hole 16. The second portion 12 is a portion that includes the first surface 10a of the substrate 10. The second portion 12 forms the opening 17a of the through hole 16 proximate to the first surface 10a. The second portion 12 defines the diameter of a part (hole portion 16b) of the through hole 16 between the first portion 11 and the first surface 10a.

The electrode 20 is disposed in the through hole 16 in the second portion 12. That is, the electrode 20 is disposed in the hole portion 16b. In other words, the second portion 12 is a portion of the substrate 10 in which the electrode 20 is disposed. The electrode 20 is located closer to the first surface 10a than the first portion 11 and the third portion 13 in the Z-direction. The electrode 20 is not provided in the first portion 11 and the third portion 13.

An inner surface 18b of the through hole 16 (the inner surface of the hole portion 16b) in the second portion 12 extends, for example, along the Z-direction. The inner surface 18b may include a portion extending substantially parallel to the Z-direction. In this example, a diameter d17b of the opening 17b is larger than a diameter d16b of the through hole 16 (the diameter of the hole portion 16b) in the second portion 12.

The third portion 13 is located between the first portion 11 and the second portion 12, and includes yet another part (hole portion 16c) of the through hole 16. The hole portion 16c is aligned with the hole portion 16a and the hole portion 16c in the Z-direction and connects the hole portion 16a and the hole portion 16c. The third portion 13 defines the diameter of a part (hole portion 16c) of the through hole 16 between the first portion 11 and the second portion 12.

For example, a diameter d16c of the through hole 16 (the diameter of the hole portion 16c) in the third portion 13 is smaller than the diameter d16b in the second portion 12. In this example, an inner surface 18c of the through hole 16 (the inner surface of the hole portion 16c) in the third portion 13 extends along the Z-direction. The diameter d16c in the third portion 13 may be constant along the Z-direction. For example, the diameter d16a in the first portion 11 is larger than the diameter d16c in the third portion 13.

The electronic device 101 further includes an insulating layer 41 and an insulating layer 42. The insulating layer 41 is located between the second portion 12 of the substrate 10 and the first electrode 21. The insulating layer 41 is in contact with the inner surface 18b of the through hole 16 in the second portion 12 and a side surface of the first electrode 21. The first electrode 21 is electrically insulated from the substrate 10 by the insulating layer 41. Similarly, the insulating layer 42 is located between the second portion 12 of the substrate 10 and the second electrode 22. The insulating layer 42 is in contact with the inner surface 18b of the through hole 16 in the second portion 12 and a side surface of the second electrode 22. The second electrode 22 is electrically insulated from the substrate 10 by the insulating layer 42. The insulating layer 41 and the insulating layer 42 may be formed of one contiguous insulating layer. The insulating layers 41 and 42 may be interlayer insulating films. That is, a wiring layer may be provided inside the insulating layers 41 and 42.

The electronic device 101 further includes, for example, a wiring layer 51, a wiring layer 52, a connection electrode 53, and a connection electrode 54. The wiring layer 51 is provided on the insulating layer 41 that is on top of the first surface 10a of the substrate 10. The wiring layer 52 is provided, for example, on top of the insulating layer 42 that is on top of the first surface 10a of the substrate 10. For example, when the wiring layer 51 is in contact with an end portion of the first electrode 21 proximate to the first surface 10a, the wiring layer 51 is electrically connected to the first electrode 21. For example, when the wiring layer 52 is in contact with an end portion of the second electrode 22 proximate to the first surface 10a, the wiring layer 52 is electrically connected to the second electrode 22. The connection electrode 53 is provided on top of the wiring layer 51 and is electrically connected to the wiring layer 51. The connection electrode 54 is provided on top of the wiring layer 52 and is electrically connected to the wiring layer 52.

The wiring layer 51, the wiring layer 52, the connection electrode 53, and the connection electrode 54 are used to, for example, electrically connect the electronic device 101 and another device. In other words, the connection electrode 53 and the connection electrode 54 are electrode pads. For example, the voltage between the first electrode 21 and the second electrode 22 is set via the wiring layer 51, the wiring layer 52, the connection electrode 53, and the connection electrode 54. The voltage between the first electrode 21 and the second electrode 22 is set by, for example, another device connected via the connection electrode 53 and the connection electrode 54.

However, the method of setting the voltage between the first electrode 21 and the second electrode 22 is not limited to the above. For example, a control circuit for setting the voltage between the first electrode 21 and the second electrode 22 may be provided to the substrate 10. For example, when the substrate 10 is a semiconductor substrate, for example, a CMOS circuit may be provided in advance to the substrate 10. A wiring layer that connects the control circuit and the electrode 20 may be provided, for example, inside the substrate 10. The wiring layer 51, the wiring layer 52, the connection electrode 53, and the connection electrode 54 are provided as necessary and can be omitted.

As shown in FIG. 2, in this example, the planar shape (the shape in the X-Y plane as viewed along the Z-direction) of the through hole 16 is an octagon. The planar shape of the opening 17b (and the planar shape of the hole portion 16a) is, for example, an octagon. However, the planar shape of the through hole 16 is not limited to this, and may be any shape, such as a quadrangle or a circle.

As described above, in the first portion 11 (see FIG. 1) of the substrate 10, the through hole 16 spreads, for example, in an isotropic manner. In this case, the planar shape of the opening 17b (and the planar shape of the hole portion 16a) is, for example, similar to the planar shape of the hole portion 16c formed by the inner surface 18c of the through hole 16. Alternatively, the opening 17b (and the hole portion) has, for example, an octagonal planar shape spreading outward while reflecting the planar shape of the hole portion 16c formed by the inner surface 18c of the through hole 16. The planar shape of the hole portion 16b (see FIG. 1) in the second portion 12 may be a shape different from a shape similar to the planar shape of the opening 17b.

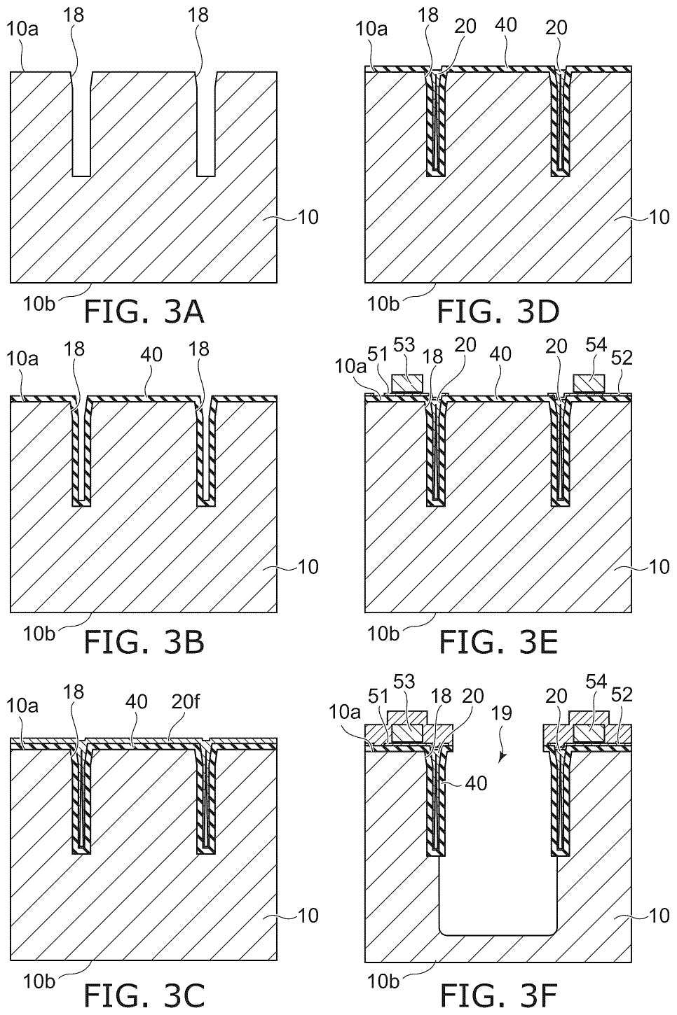

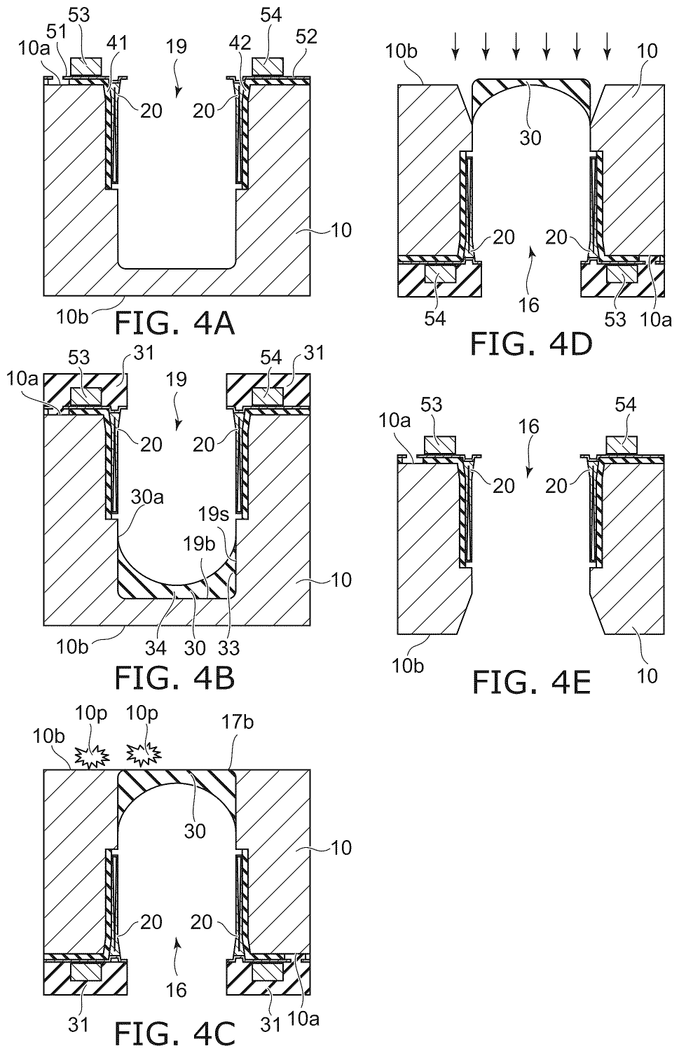

FIGS. 3A to 3F and FIGS. 4A to 4E are schematic cross-sectional views illustrating a method for manufacturing the electronic device according to the embodiment.

As shown in FIG. 3A, a process of forming a groove 18 in the first surface 10a of the substrate 10 is performed. As the substrate 10, for example, a silicon substrate can be used. The groove 18 is formed by, for example, lithography and etching. The width of the groove 18 is, for example, about 2 μm (for example, 1 μm or more and 3 μm or less). The depth of the groove 18 is, for example, 10 μm or more and 60 μm or less. As will be described later, an electrode is formed in the groove 18. For example, a pair of electrodes is disposed. After a through hole is formed, an electron beam passes between the pair of electrodes.

As shown in FIG. 3B, a process of forming an insulating film 40 inside the groove 18 is performed. The insulating film 40 is an insulating film that serves as the insulating layer 41 and the insulating layer 42 described above (see FIG. 1). More specifically, the insulating film 40 is formed on the entire surface of the first surface 10a side of the substrate 10, and the insulating film 40 is formed on the inner side surface of the groove 18. For example, silicon oxide can be used for the insulating film 40.

As shown in FIG. 3C, a conductive film 20f, which serves as the electrode 20, is formed on top of the entire surface of the insulating film 40, and the conductive film 20f is formed on the inner side of the insulating film 40 in the groove 18. For example, a vapor phase growth method is used to form the conductive film 20f. The material of the conductive film 20f (the material of the electrode 20) is, for example, tungsten (W), gold (Au), copper (Cu), aluminum (Al), or titanium nitride (TiN). The conductive film 20f (the material of the electrode 20) may include multiple materials. The groove 18 might not be sufficiently filled with the conductive film 20f formed by vapor phase growth at a deep position thereof. Therefore, the electrode 20 may have a hollow structure. When the thickness of the conductive film 20f is adjusted, the upper portion of the groove 18 is closed by the formation of the conductive film 20f proceeding from both sides of the groove 18. For the formation of the conductive film 20f, a vapor phase growth method such as an ALD method, a plating method, or a sputtering method may be used in addition to embedding by CVD.

Thereafter, as shown in FIG. 3D, the conductive film 20f formed on top of the insulating film 40 outside the groove 18 is removed by etching. As a result, the electrode 20 embedded in the groove 18 is formed from the conductive film 20f. As described above, the method for manufacturing the electronic device includes a process of forming the electrode 20 extending in the Z-direction in the substrate 10. The process of forming the electrode 20 includes forming the electrode 20 on the inner side of the insulating film 40 in the groove 18.

As shown in FIG. 3E, the wiring layer 51 and the wiring layer 52, which are electrically connected to the upper portions of the exposed electrodes 20, are formed. For example, a metal layer, which serves as a wiring layer, is formed on top of the insulating film 40 and on top of the electrode 20, and the metal layer is patterned by lithography and etching. The metal layer is removed by etching in an area in which a through hole is to be formed thereafter. Further, the connection electrode 53 and the connection electrode 54 are formed on top of the wiring layer 51 and the wiring layer 52 as necessary. For example, a conductive material, such as TiN, is used for the wiring layer 51 and the wiring layer 52. For example, a metal material, such as Au, is used for the connection electrode 53, and the connection electrode 54.

Next, for example, a through hole is formed between the pair of electrodes 20. The through hole is formed by processing the substrate 10 by, for example, resist patterning and etching. The thickness of the substrate 10 may be, for example, 700 μm or more before the through hole is formed. In this case, it may be difficult to form a through hole that penetrates the substrate 10 in one process. Therefore, first, a recess, which serves as the through hole, is formed from the first surface 10a side of the substrate 10. For example, a recess deeper than a final desired thickness of the substrate is formed in advance. Thereafter, the second surface 10b side of the substrate is cut, thereby forming the through hole.

Specifically, as shown in FIG. 3F, a process of forming a recess 19 in the first surface 10a of the substrate 10 is performed. In the process of forming the recess 19, the recess 19 is formed so as to be aligned with the electrode 20 and the insulating film 40 in a direction intersecting the Z-direction. Accordingly, the insulating film 40 formed on the side surface of the electrode 20 embedded in the groove 18 is exposed. The recess 19 is formed between the pair of grooves 18 by, for example, lithography and etching.

The recess 19 is deeper than the groove 18. In other words, in the Z-direction, the bottom of the recess 19 is between the bottom of the groove 18 and the second surface 10b. The depth of the recess 19 can be, for example, 100 μm or more and 200 μm or less (for example, about 155 μm).

Thereafter, as shown in FIG. 4A, a process of exposing the electrode 20 in the recess 19 is performed. This process includes removing a part of the insulating film 40 shown in FIG. 3F. For example, the insulating film 40 shown in FIG. 3F is removed by etching using an etchant containing fluorine, in an area including a portion exposed in the recess 19. For example, the oxide film is etched with, for example, HF gas. Accordingly, the entire side surface of the electrode 20 at the recess 19 side is exposed in the recess 19. As a result, the insulating layer 41 and the insulating layer 42 are formed from the insulating film 40. The side surfaces of the pair of electrodes 20 face each other across the recess 19.

Thereafter, as shown in FIG. 4B, a process of forming a protective film 30 inside the recess 19 is performed. The protective film 30 is formed by, for example, applying an organic material, such as a resist or polyimide.

An end portion of the protective film 30 facing the second surface 10b covers a bottom surface 19b of the recess 19. For example, the entire bottom surface 19b of the recess 19 is in contact with the end portion of the protective film 30. A part of a side surface 19s of the recess is in contact with the protective film 30. The height of the protective film 30 from the bottom surface 19b is lower than that of the first surface 10a of the substrate 10. In other words, the recess 19 is not completely filled with the protective film 30. In the Z-direction, an upper end 30a (an end proximate to the first surface 10a in the X-direction) of the protective film 30 is between the first surface 10a and the bottom surface 19b. The protective film 30 need not be necessarily formed on the exposed side surface of the electrode 20. In the recess 19, a space may be formed above the protective film 30 (in proximity to the first surface 10a). A portion of the electrode 20 above the protective film 30 is in contact with the space in the recess 19.

Thereafter, as shown in FIG. 4C, a process of processing the substrate 10 from the second surface 10b is performed. For example, the substrate 10 is thinned to a desired thickness by etching or cutting from the second surface 10b. The desired thickness of the substrate 10 is, for example, about 100 μm or more and 200 μm or less. For example, when the depth of the recess 19 is 155 μm, the thickness of the substrate 10 is set to about 150 μm. Accordingly, the protective film 30 provided in the recess 19 is exposed in the second surface 10b of the substrate 10. When the end portion of the protective film 30 covering the bottom surface 19b of the recess 19 is exposed, the through hole 16 is formed from at least a part of the recess 19. As described above, for example, a part of the recess 19 and a part of the groove 18 (see FIG. 3A) become the through hole 16.

As shown in FIG. 4C, when the substrate 10 is thinned, the through hole 16 is covered with the protective film 30. That is, the opening 17b of the through hole 16 opposite to the first surface 10a is closed by the protective film 30.

As shown in FIG. 4C, an adhesive material 31 may be provided at the first surface 10a side of the substrate 10, and a support (such as a support substrate) not illustrated may be attached to the substrate 10 with the adhesive material 31. The adhesive material 31 may be formed simultaneously with the protective film 30. The adhesive material 31 need not be provided in the recess 19 and need not be in contact with the electrode 20. The first surface 10a of the substrate 10 may be supported by, for example, an adhesive tape.

When the substrate 10 is processed, foreign matter may enter the through hole 16. For example, when the substrate 10 is thinned by a cutting method, chips 10p (foreign matter, dust) are originated from the substrate 10. Since the protective film 30 closes the through hole 16, the foreign matter can be prevented from entering the through hole 16.

In this example, after the process of processing the substrate 10 from the second surface 10b and before a process of removing the protective film 30, a process of etching the second surface 10b of the substrate 10 is performed as shown in FIG. 4D. For the etching, for example, dry etching or isotropic etching is used. The chips 10p originated in the thinning of the substrate 10 can be removed from the front surface side (second surface 10b) of the substrate 10 by the etching process and a cleaning process.

In this etching, the thickness of the substrate 10 is slightly reduced. At the same time, for example, etching gas enters the boundary between the protective film 30 and the substrate 10. In the inner surface of the through hole 16, a region that is in contact with the protective film 30 and is proximate to the second surface 10b is removed. Accordingly, the diameter (cross-sectional area) of the through hole 16 proximate to the second surface 10b after the removal of the protective film 30 increases.

Thereafter, as shown in FIG. 4E, the process of removing the protective film 30 provided in the through hole 16 is performed. For example, the organic material, which is the protective film 30, is removed by a solvent or ashing. When the protective film 30 is removed, the first surface 10a and the second surface 10b communicate with each other via the through hole 16. The protective film 30 is not limited to an organic material, such as a resist or polyimide, and a material that can be removed after the formation of the through hole 16 can be used as appropriate.

Accordingly, the electronic device 101 according to the embodiment can be manufactured.

When foreign matter (for example, chips originated by cutting of the substrate) adheres to the inside of the through hole of the substrate, a defect of the electronic device may occur. For example, the yield of the electronic device decreases. In contrast, in the embodiment, since the protective film 30 is provided, the foreign matter can be prevented from entering the through hole 16 from the opening 17b of the through hole 16. Accordingly, for example, the occurrence of defects can be reduced. For example, as shown in FIG. 4A, the electrode 20 is exposed in the recess 19. According to the embodiment, foreign matter can be prevented from adhering to the exposed electrode 20.

Further, since the back surface side of the substrate 10 is etched as described with reference to FIG. 4D, foreign matter can be removed. Further, since the protective film 30 is provided upon the etching, the electrode 20 exposed in the through hole 16 can be prevented from being damaged by the etching. Accordingly, for example, the occurrence of defects can be further reduced.

For example, as shown in FIG. 4B, the protective film 30 includes an outer portion 33 located in the recess 19 close to the outside and an inner portion 34 located in the recess 19 closer to the inside than the outer portion 33. The inner portion 34 is located at the center of the recess 19 in the X-Y plane. The outer portion 33 is in contact with the side surface 19s of the recess 19. The outer portion 33 is located between the side surface 19s of the recess 19 and the inner portion 34 in the X-Y plane. In this example, the outer portion 33 is thicker than the inner portion 34. In other words, the length of the outer portion 33 along the Z-direction is longer than the length of the inner portion 34 along the Z-direction. When the protective film 30 is formed thick, even if the side surface of the protective film 30 is exposed by the etching process described with reference to FIG. 4D, the protective film 30 closes the opening of the through hole 16, and therefore, foreign matter can be further prevented from entering the through hole 16.

For example, when the back surface side of the substrate 10 is processed after the recess is formed from the front side of the substrate 10 in order to form the through hole in the substrate 10, another support substrate may be bonded to the front surface side of the substrate 10. At this time, there is a method of a reference example in which a recess formed in the front side of the substrate 10 is filled with an organic material (adhesive material). In the method of the reference example, for example, an organic material is applied to the front surface side of the substrate 10 and baked, thereby attaching a support substrate of a glass material. Then, the substrate 10 is flipped so that the support substrate faces downward, and the upper side (back surface side of the substrate) is etched. In the reference example as described above, the electrode exposed in the recess of the substrate 10 may receive a force from the organic material embedded in the recess and may be deformed or broken. For example, when the organic material is applied and cured, the organic material shrinks. Accordingly, stress is applied to the electrode in the side surface or the corner portion that is in contact with the organic material, and distortion occurs. As a result, the electrode may be deformed or broken. In particular, when the electrode 20 is hollow, deformation or breakage may easily occur.

In contrast, as described with reference to FIG. 4B, the height of the protective film 30 from the bottom surface 19b of the recess 19 is lower than that of the first surface 10a. That is, the recess 19 is not completely filled with the protective film 30. Accordingly, the electrode 20 and the protective film 30 can be prevented from coming in contact with each other. The electrode 20 can be prevented from receiving a force from the protective film 30. For example, deformation and breakage of the electrode 20 are prevented, and the occurrence of defects can be further reduced. For example, even if the electrode 20 is hollow, the occurrence of defects can be reduced.

The protective film 30 need not be in contact with the electrode 20. The recess 19 is deeper than the groove 18 and deeper than the end portion of the electrode 20 proximate to the second surface 10b. Since the recess 19 is deep, the protective film 30 provided on the bottom of the recess 19 can be prevented from coming into contact with the electrode 20. For example, the protective film 30 is below the electrode 20. That is, the position of the protective film 30 in the Z-direction is between the position of the electrode 20 in the Z-direction and the position of the second surface 10b in the Z-direction. Accordingly, for example, the protective film 30 does not come into contact with the electrode 20, and the occurrence of defects can be further reduced.

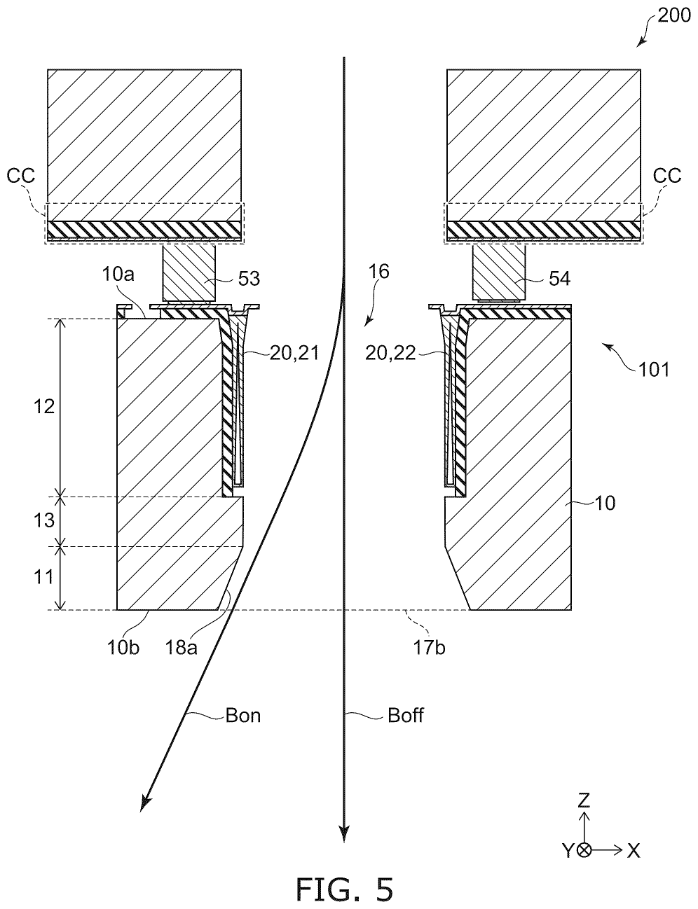

FIG. 5 is a schematic cross-sectional view of the electronic device according to the embodiment.

As shown in FIG. 5, in this example, the electronic device 101 is stacked with a control substrate 200 including a control circuit CC. The control circuit CC includes, for example, a CMOS circuit, and is an LSI (large scale integration) circuit formed in the control substrate 200. In FIG. 5, the control circuit CC is illustrated in a simplified manner for the sake of convenience. The electronic device 101 may include the control substrate 200 (control circuit CC).

The pair of electrodes 20 is connected to the control circuit CC with the connection electrode 53 and the connection electrode 54 interposed therebetween. The control circuit CC controls the voltage between the pair of electrodes 20, thereby controlling the travel direction of the electron beam passing through the through hole 16 from the first surface 10a toward the second surface 10b.

The line Boff shown in FIG. 5 is an example of the electron beam when the control circuit CC does not apply a voltage between the pair of electrodes 20. The line Bon is an example of the electron beam when the control circuit CC applies a voltage between the pair of electrodes 20. As illustrated, the electron beam having passed through a through hole provided in the control substrate 200 travels from between the pair of electrodes 20 provided in the second portion 12 of the substrate 10 to the first portion 11, and passes through the through hole 16.

For example, the control circuit CC sets one of the pair of electrodes 20 at the ground and controls the voltage of the other. Alternatively, the control circuit CC may control the potentials of both the electrodes 20. Two or more pairs of electrodes 20 may be provided. The control circuit CC may be provided to the substrate 10.

As described above with reference to FIG. 4D, for example, in the manufacturing of the electronic device 101, the process of etching the second surface 10b side of the substrate 10 is performed. In this process, as shown in FIG. 5, the diameter of the through hole 16 in the first portion 11 of the substrate 10 is increased as the through hole 16 extends toward the opening 17b in the Z-direction. For example, in this etching process, the diameter of the through hole 16 in the first portion 11 is increased in the X-Y plane in an isotropic manner. According to the embodiment, the diameter of the opening 17b can be increased, and the direction of the electron beam can be changed to a large degree as, for example, shown by the line Bon in FIG. 5.

Since the second surface 10b of the substrate 10 is etched as described above, the through hole 16 can be formed so that its cross-sectional area after removal the protective film 30 is large. Therefore, even if the angle of deflection of the electron beam is increased by an electric field generated by the electrode 20, for example, the electron beam does not interfere with the substrate 10. For example, a defect in which the electron beam and the substrate 10 unintentionally interfere with each other can be prevented.

As already described with reference to FIG. 1, for example, the diameter of the opening 17b is larger than the diameter of the through hole 16 in the second portion 12. For example, the diameter of the opening 17b is larger than the diameter of the through hole 16 in the third portion 13. Further, for example, the inner surface 18a of the through hole 16 in the first portion 11 is an inclined surface that is inclined with respect to the Z-direction. With such a configuration, for example, the interference of the electron beam with the substrate 10 is further prevented.

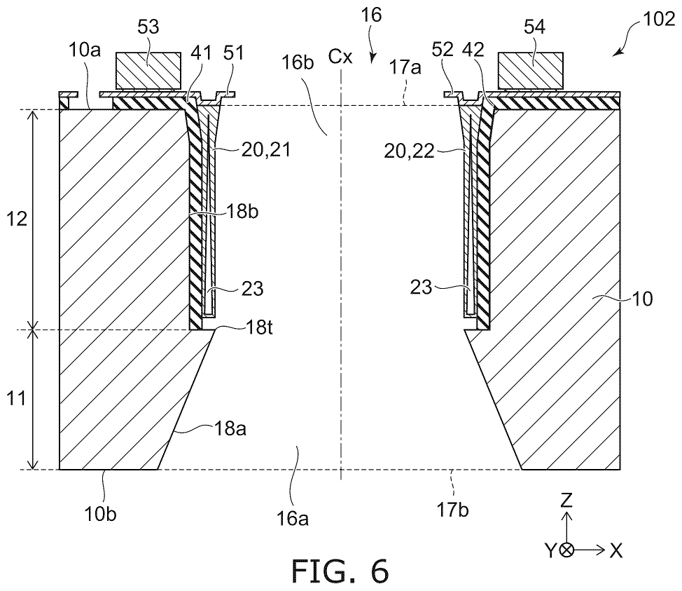

FIG. 6 is a schematic cross-sectional view of an electronic device according to the embodiment.

As shown in FIG. 6, in an electronic device 102 according to the embodiment, the through hole 16 has a shape spreading toward the opening 17b in substantially the entire area below the electrode 20.

In this example, the entire inner surface 18a of the through hole 16 in the first portion 11 of the substrate 10 is an inclined surface that is inclined toward the outside of the through hole 16 as the inner surface 18a extends toward the opening 17b. An upper end 18t of the inclined inner surface 18a (an end proximate to the first surface 10a in the Z-direction) is, for example, located directly below the electrode 20. The surface directly contiguous from the upper end 18t of the inner surface 18a need not extend along the Z-direction. For example, the substrate 10 need not include the third portion 13 described with reference to FIG. 1, and the first portion 11 may be directly contiguous from below the second portion 12.

The electronic device 102 can be similarly manufactured as in the above-described manufacturing method by adjusting the amount of etching described with reference to FIG. 4D. Also in the electronic device 102, entry of foreign matter into the through hole 16 and deformation and breakage of the electrode 20 can be prevented. Since the through hole 16 in the first portion 11 spreads toward the opening 17b, for example, interference between the deflected electron beam and the substrate 10 can be prevented.

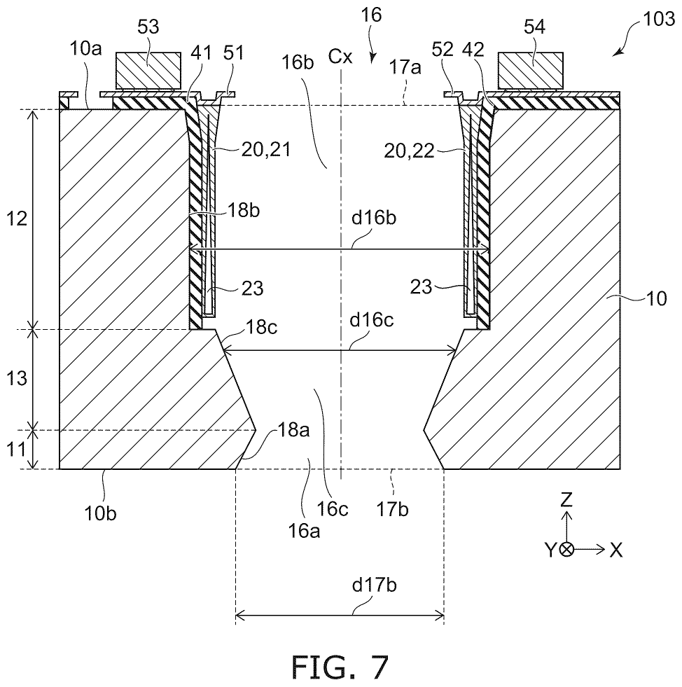

FIG. 7 is a schematic cross-sectional view of an electronic device according to the embodiment.

As shown in FIG. 7, in an electronic device 103 according to the embodiment, the through hole 16 has a shape that narrows on the way below the electrode 20. The inner surface 18c in the third portion 13 of the substrate 10 is an inclined surface that is inclined with respect to the Z-direction.

In this example, the inner surface 18c in the third portion 13 is inclined so as to be closer the center Cx of the through hole 16 as the inner surface 18c extends toward the opening 17b in the Z-direction. The diameter of the through hole 16 in the third portion 13 decreases as the through hole 16 extends toward the opening 17b in the Z-direction. The diameter d17b of the opening 17b may be smaller than the diameter d16b of the through hole 16 in the second portion 12. The diameter d17b of the opening 17b may be smaller than the diameter d16c of the through hole 16 in the upper portion of the third portion 13.

The electronic device 103 can be similarly manufactured as in the above-described manufacturing method by adjusting the etching conditions described with reference to FIG. 3F to form the side surface of the recess 19 into an inclined surface. When the recess 19 has the inclined surface, for example, the recess 19 is easily formed. Also in the electronic device 103, entry of foreign matter into the through hole 16 and deformation and breakage of the electrode 20 can be prevented. Since the through hole 16 in the first portion 11 spreads toward the opening 17b, for example, interference between the deflected electron beam and the substrate 10 can be prevented.

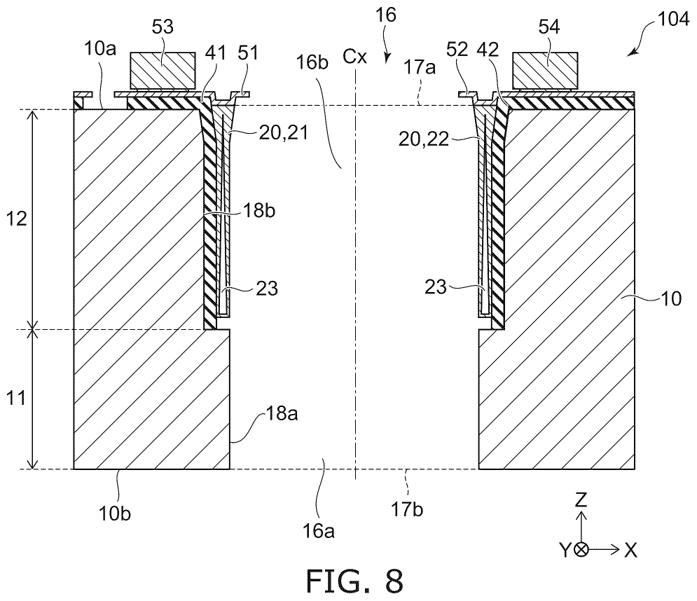

FIG. 8 is a schematic cross-sectional view of an electronic device according to the embodiment.

As shown in FIG. 8, in an electronic device 104 according to the embodiment, the through hole 16 has a shape extending along the Z-direction. That is, the inner surface 18a in the first portion 11 of the substrate 10 extends along the Z-direction. The inner surface 18a may be parallel to the Z-direction.

The electronic device 104 can be manufactured similarly as in the above-described manufacturing method by omitting the etching process described with reference to FIG. 4D. For example, an increase in the number of processes can be reduced. Also in the electronic device 104, entry of foreign matter into the through hole 16 and deformation and breakage of the electrode 20 can be prevented.

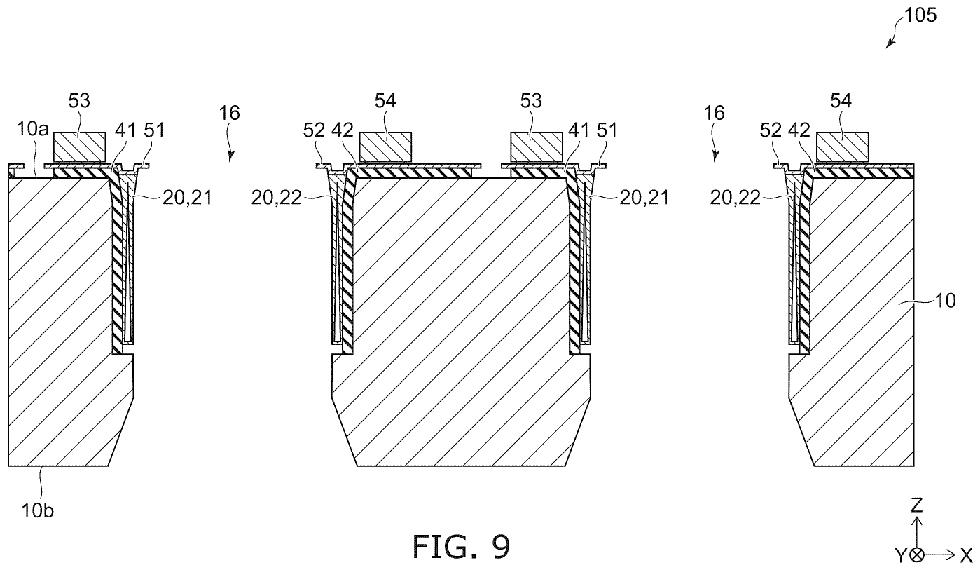

FIG. 9 is a schematic cross-sectional view of an electronic device according to the embodiment.

As shown in FIG. 9, in an electronic device 105 according to the embodiment, the substrate 10 has a plurality of through holes 16. The electronic device 105 includes a plurality of electrodes 20 (a plurality of first electrodes 21 and a plurality of second electrodes 22) respectively provided in the plurality of through holes 16.

The number of through holes 16 provided in the electronic device may be any number. The number of through holes 16 provided in the electronic device may be set as appropriate in accordance with, for example, the use of the electronic device.

The embodiments may include the following configurations (for example, technical ideas).

### Configuration 1

A method for manufacturing an electronic device, the method including:
forming a recess on a first surface side of a substrate, the substrate having the first surface and a second surface opposite to the first surface;
forming a protective film inside the recess, an end portion of the protective film covering a bottom surface of the recess, a height of the protective film from the bottom surface being lower than a height of the first surface;
processing the substrate from the second surface side to expose the end portion of the protective film to form a through hole in the substrate from at least a part of the recess, an opening of the through hole on a side opposite to the first surface being closed by the protective film; and
removing the protective film provided in the through hole.

### Configuration 2

The method according to configuration 1, further including:
after the processing of the substrate from the second surface side and before the removing of the protective film, etching the second surface side of the substrate.

### Configuration 3

The method according to configuration 1 or 2, further including:
forming an electrode in the substrate, the electrode extending along a first direction from the second surface toward the first surface, in which
the electrode is exposed in the recess.

### Configuration 4

The method according to configuration 3, in which
the recess is deeper than an end portion of the electrode at the second surface side.

### Configuration 5

The method according to configuration 3 or 4, in which
the electrode is hollow.

### Configuration 6

The method according to any one of configurations 3 to 5, further including:
forming a groove on the first surface side of the substrate; and
forming an insulating film inside the groove, in which
in the forming of the electrode, the electrode is formed inside the insulating film in the groove.

### Configuration 7

The method according to configuration 6, further including:
after the forming of the recess, exposing the electrode in the recess, in which
in the forming of the recess, the recess is formed so as to be aligned with the electrode in a second direction intersecting the first direction, the electrode being provided in the groove, and
the exposing of the electrode includes removing a part of the insulating film.

### Configuration 8

The method according to any one of configurations 3 to 7, in which
the protective film is not in contact with the electrode.

### Configuration 9

The method according to any one of configurations 3 to 8, in which
a position of the protective film in the first direction is between a position of the electrode in the first direction and a position of the second surface in the first direction.

### Configuration 10

The method according to configuration 2, in which
the substrate in which the through hole has been formed includes a first portion, the first portion forming the opening of the through hole on the side opposite to the first surface, and
in the etching of the second surface side of the substrate, a diameter of the through hole in the first portion is increased as the through hole extends toward the opening in a first direction, the first direction being a direction from the second surface toward the first surface.

### Configuration 11

The method according to configuration 10, in which
in the etching of the second surface side of the substrate, the diameter of the through hole in the first portion is increased in a plane perpendicular to the first direction in an isotropic manner.

### Configuration 12

The method according to any one of configurations 1 to 11, in which
the protective film includes an outer portion and an inner portion, the outer portion being in contact with a side surface of the recess, the inner portion being located in the recess closer to an inside than the outer portion, and
a length of the outer portion along a first direction from the second surface toward the first surface is longer than a length of the inner portion along the first direction.

### Configuration 13

An electronic device including:
a substrate having a first surface, a second surface opposite to the first surface, and a through hole extending along a first direction from the second surface toward the first surface; and
an electrode provided in the through hole and extending along the first direction,
the substrate including
   a first portion including an opening of the through hole at the second surface side, and
   a second portion located between the first portion and the first surface and including a part of the through hole,
the electrode being disposed in the through hole in the second portion and being located closer to the first surface than the first portion,
a diameter of the through hole in the first portion increasing as the through hole extends toward the opening in the first direction.

### Configuration 14

The electronic device according to configuration 13, in which
a diameter of the opening is larger than a diameter of the through hole in the second portion.

### Configuration 15

The electronic device according to configuration 13 or 14, in which
an inner surface of the through hole in the first portion is an inclined surface inclined with respect to the first direction.

### Configuration 16

The electronic device according to any one of configurations 13 to 15, in which
the substrate includes a third portion, the third portion being located between the first portion and the second portion and including another part of the through hole, and
a diameter of the through hole in the third portion is smaller than a diameter of the through hole in the second portion.

### Configuration 17

The electronic device according to configuration 16, in which
an inner surface of the through hole in the third portion extends along the first direction.

### Configuration 18

The electronic device according to configuration 16, in which
an inner surface of the through hole in the third portion is an inclined surface inclined with respect to the first direction, and
the diameter of the through hole in the third portion decreases as the through hole extends toward the opening in the

### Configuration 19

The electronic device according to any one of configurations 13 to 18, in which
a plurality of the electrodes is included,
the substrate includes a plurality of the through holes, and
the plurality of electrodes are respectively provided in the plurality of through holes.

### Configuration 20

The electronic device according to any one of configurations 13 to 19, in which
the electrode includes a pair of electrodes facing each other across a center of the through hole in a plane perpendicular to the first direction,
the pair of electrodes are electrically connected to a control circuit, and
the control circuit controls a voltage between the pair of electrodes, thereby controlling a travel direction of an electron beam passing through the through hole from the first surface side toward the second surface side.

According to the embodiment, a method for manufacturing an electronic device and an electronic device capable of reducing the occurrence of defects can be provided.

In the specification, a case of “being electrically connected” includes a case of “being connected by direct contact” and also includes a case of “being connected with, for example, another conductive member interposed”.

In the specification, “perpendicular” and “parallel” not only refer to strictly perpendicular and strictly parallel but also allow, for example, variations caused during, for example, the manufacturing process, and need to be substantially perpendicular and substantially parallel.

Certain embodiments of the invention have been described above with reference to specific examples. However, the invention is not limited to these specific examples. For example, those skilled in the art may similarly practice the invention by selecting, as appropriate, specific configurations of components included in the electronic devices from known art. Such practice is included in the scope of the invention to the extent that similar effects are attained.

Any two or more components in the specific examples may be combined within the extent of technical feasibility and are included in the scope of the invention to the extent that the spirit of the invention is included.

Moreover, all electronic devices and manufacturing methods practicable by an appropriate design modification by those skilled in the art based on the electronic devices and manufacturing methods described above as embodiments of the invention also are within the scope of the invention to the extent that the spirit of the invention is included.

Moreover, various variations and modifications can be conceived by those skilled in the art within the spirit of the invention, and it is understood that such variations and modifications are also encompassed within the scope of the invention.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the invention.

What is claimed is:

1. A method for manufacturing an electronic device, the method comprising:
forming a recess on a first surface side of a substrate, the substrate having the first surface and a second surface opposite to the first surface;
forming a protective film inside the recess, an end portion of the protective film covering a bottom surface of the recess, a height of the protective film from the bottom surface being lower than a height of the first surface;
processing the substrate from the second surface side to expose the end portion of the protective film to form a through hole in the substrate from at least a part of the recess, an opening of the through hole on a side opposite to the first surface being closed by the protective film; and
removing the protective film provided in the through hole.

2. The method according to claim 1, further comprising:
after the processing of the substrate from the second surface side and before the removing of the protective film, etching the second surface side of the substrate.

3. The method according to claim 1, further comprising:
forming an electrode in the substrate, the electrode extending along a first direction from the second surface toward the first surface, wherein
the electrode is exposed in the recess.

4. The method according to claim 3, wherein
the recess is deeper than an end portion of the electrode at the second surface side.

5. The method according to claim 3, wherein
the electrode is hollow.

6. The method according to claim 3, further comprising:
forming a groove on the first surface side of the substrate; and
forming an insulating film inside the groove, wherein
in the forming of the electrode, the electrode is formed inside the insulating film in the groove.

7. The method according to claim 6, further comprising:
after the forming of the recess, exposing the electrode in the recess, wherein
in the forming of the recess, the recess is formed so as to be aligned with the electrode in a second direction intersecting the first direction, the electrode being provided in the groove, and
the exposing of the electrode includes removing a part of the insulating film.

8. The method according to claim 3, wherein
the protective film is not in contact with the electrode.

9. The method according to claim 3, wherein
a position of the protective film in the first direction is between a position of the electrode in the first direction and a position of the second surface in the first direction.

10. The method according to claim 2, wherein
the substrate in which the through hole has been formed includes a first portion, the first portion forming the opening of the through hole on the side opposite to the first surface, and
in the etching of the second surface side of the substrate, a diameter of the through hole in the first portion is increased as the through hole extends toward the opening in a first direction, the first direction being a direction from the second surface toward the first surface.

11. The method according to claim 10, wherein
in the etching of the second surface side of the substrate, the diameter of the through hole in the first portion is increased in a plane perpendicular to the first direction in an isotropic manner.

12. The method according to claim 1, wherein
the protective film includes an outer portion and an inner portion, the outer portion being in contact with a side surface of the recess, the inner portion being located in the recess closer to an inside than the outer portion, and
a length of the outer portion along a first direction from the second surface toward the first surface is longer than a length of the inner portion along the first direction.

13. An electronic device comprising:
a substrate having a first surface, a second surface opposite to the first surface, and a through hole extending along a first direction from the second surface toward the first surface; and
an electrode provided in the through hole and extending along the first direction,
the substrate including
a first portion including an opening of the through hole at the second surface side, and
a second portion located between the first portion and the first surface and including a part of the through hole,
the electrode being disposed in the through hole in the second portion and being located closer to the first surface than the first portion,
a diameter of the through hole in the first portion increasing as the through hole extends toward the opening in the first direction.

14. The electronic device according to claim 13, wherein
a diameter of the opening is larger than a diameter of the through hole in the second portion.

15. The electronic device according to claim 13, wherein
an inner surface of the through hole in the first portion is an inclined surface inclined with respect to the first direction.

16. The electronic device according to claim 13, wherein
the substrate includes a third portion, the third portion being located between the first portion and the second portion and including another part of the through hole, and
a diameter of the through hole in the third portion is smaller than a diameter of the through hole in the second portion.

17. The electronic device according to claim 16, wherein
an inner surface of the through hole in the third portion extends along the first direction.

18. The electronic device according to claim 16, wherein
an inner surface of the through hole in the third portion is an inclined surface inclined with respect to the first direction, and
the diameter of the through hole in the third portion decreases as the through hole extends toward the opening in the first direction.

19. The electronic device according to claim 13, wherein
a plurality of the electrodes is included,
the substrate includes a plurality of the through holes, and
the plurality of electrodes are respectively provided in the plurality of through holes.

20. The electronic device according to claim 13, wherein
the electrode includes a pair of electrodes facing each other across a center of the through hole in a plane perpendicular to the first direction,
the pair of electrodes are electrically connected to a control circuit, and
the control circuit controls a voltage between the pair of electrodes, thereby controlling a travel direction of an electron beam passing through the through hole from the first surface side toward the second surface side.
